(19) United States
(12) Patent Application Publication
(10) Pub. No.: US 2026/0190286 A1
(43) Pub. Date: Jul. 2, 2026

(54) COOLING SYSTEM AND CONTROL METHOD THEREOF

(71) Applicant: Industrial Technology Research Institute, Hsinchu (TW)

(72) Inventors: Wen-Chih Chen, Hsinchu County (TW); Chun-Kai Liu, Hsinchu City (TW); Po-Kai Chiu, Taoyuan City (TW); Ting-Yu Wang, Kaohsiung City (TW); Yao-Shun Chen, Hsinchu County (TW); Chien-Chun Lu, New Taipei City (TW)

(73) Assignee: Industrial Technology Research Institute, Hsinchu (TW)

(21) Appl. No.: 19/090,405

(22) Filed: Mar. 26, 2025

(30) Foreign Application Priority Data
Dec. 30, 2024 (TW) 113151555

(51) Int. Cl. H05K 7/20

(52) U.S. Cl. CPC H05K 7/20272; H05K 7/20263; H05K 7/20409; H05K 7/20927; H05K 7/20945

(57) ABSTRACT

A cooling system including a power module and at least one cooling structure is provided. The power module has a top surface and a bottom surface opposite to each other. The at least one of the top surface or the bottom surface is connected to the at least one cooling structure. Each of the at least one cooling structure includes a substrate and a plurality of cooling fins. The plurality of cooling fins are disposed on the substrate and form a plurality of flow channels. In addition, a control method of the cooling system is also mentioned. The cooling system and control method thereof effectively improve the cooling efficiency, extend element service life, and improve the stability.

### CROSS-REFERENCE TO RELATED APPLICATION

This application claims the priority benefit of Taiwan application serial no. 113151555, filed on Dec. 30, 2024. The entirety of the above-mentioned patent application is hereby incorporated by reference herein and made a part of this specification.

### TECHNICAL FIELD

The disclosure relates to a cooling system and a control method thereof.

### BACKGROUND

Along with development of electric vehicles and related application industries such as artificial intelligence (AI) servers, the demand for high-efficiency heat sinks that may effectively dissipate heat to maintain stable operations of power systems and AI servers has increased. The high-efficiency heat sink needs to be able to dissipate heat generated by a power module at high power output. In addition, the high-efficiency heat sink needs to maintain a compact design and needs to have a lightweight design, which not only saves a space but also does not affect driving efficiency and a battery service duration.

Excessively high temperature may easily cause operating efficiency of the power module and processor elements in the server to decrease, or even cause failures. Therefore, the cooling efficiency of the heat sink may directly affect operating performance and service life of the processor elements in the power module and server. In other words, how to improve the cooling effect of the heat sink to increase reliability of electric vehicles and AI servers, reduce maintenance costs and extend the operating service life is one of the topics in this field.

### SUMMARY

The disclosure is directed to a cooling system with cooling fins and a control method thereof.

An embodiment of the disclosure provides a cooling system including a power module and at least one cooling structure. The power module has a top surface and a bottom surface opposite to each other. At least one of the top surface or the bottom surface of the power module is connected to the at least one cooling structure. Each of the at least one cooling structure includes a substrate and a plurality of cooling fins. The plurality of cooling fins are disposed on the substrate and form a plurality of flow channels.

An embodiment of the disclosure provides another cooling system including at least two power modules, a plurality of cooling structures and a manifold component. Each of the at least two power modules has a top surface and a bottom surface opposite to each other. The plurality of cooling structures are connected to at least one of the top surface and the bottom surface of each of the at least two power modules. Each of the cooling structures includes a substrate and a plurality of cooling fins. The cooling fins are disposed on the substrate and form a plurality of flow channels. The manifold component is connected to the cooling structures, and the manifold component includes at least one inlet branch pipe and at least one outlet branch pipe. The at least one inlet branch pipe includes a plurality of inlet ports connected to the cooling structures, and the inlet ports have a plurality of inlet pipe diameters of different sizes. The at least one outlet branch pipe includes a plurality of outlet ports connected to the cooling structures, and the outlet ports have a plurality of outlet pipe diameters of different sizes. A fluid flows from at least one source along an inflow direction through the at least one inlet branch pipe, the flow channels of the cooling structures and the at least one outlet branch pipe.

The disclosure further provides a control method of a cooling system. The cooling system includes at least two power modules, a plurality of cooling structures and a manifold component. The cooling structures are connected to at least one of a top surface and a bottom surface of each of the at least two power modules. At least one inlet branch pipe of the manifold component is connected to a plurality of inlet ports of the cooling structures. At least one outlet branch pipe of the manifold component is connected to a plurality of outlet ports of the cooling structures. A plurality of valve body components are disposed at the inlet ports. The control method includes following steps: sensing a temperature of the at least two power modules to obtain a plurality of temperature data; analyzing the plurality of temperature data; determining whether the temperature of the at least two power modules is abnormal; when a determination result indicates abnormality, adjusting the temperature of the at least two power modules to stabilize the temperature of the at least two power modules; when the determination result indicates no abnormality or the temperature of the at least two power modules is stabilized, recording and learning the plurality of temperature data and an adjustment process.

### BRIEF DESCRIPTION OF DRAWINGS

FIG. 1A is a schematic diagram of an appearance of a cooling system according to a first embodiment of the disclosure.

FIG. 1B is a schematic side view of the cooling system of FIG. 1A.

FIG. 1C is a schematic diagram of an appearance of a cooling structure of FIG. 1B.

FIG. 1D is a schematic top view of cooling fins of FIG. 1C.

FIG. 2 is a schematic diagram of an appearance of a cooling system according to a second embodiment of the disclosure.

FIG. 3 is a schematic diagram of an appearance of a cooling system according to a third embodiment of the disclosure.

FIG. 4A is a schematic diagram of an appearance of a cooling system according to a fourth embodiment of the disclosure.

FIG. 4B is a schematic top view of the cooling system in FIG. 4A.

FIG. 5 is a schematic diagram of an appearance of a cooling system according to a fifth embodiment of the disclosure.

FIG. 6 is a schematic diagram of an appearance of a cooling system according to a sixth embodiment of the disclosure.

FIG. 7 is a schematic diagram of an appearance of a cooling system according to a seventh embodiment of the disclosure.

FIG. 8 is a schematic diagram of an appearance of a cooling system according to an eighth embodiment of the disclosure.

FIG. 9 is a schematic diagram of an appearance of a cooling system according to a ninth embodiment of the disclosure.

FIG. 10 is a schematic diagram of an appearance of a cooling system according to a tenth embodiment of the disclosure.

FIG. 11 is a schematic top view of a cooling system according to an eleventh embodiment of the disclosure.

FIG. 12 is a schematic flowchart of a control method of a cooling system of the disclosure.

FIG. 13 is a detailed flowchart of the control method of FIG. 12.

### DETAILED DESCRIPTION OF DISCLOSED EMBODIMENTS

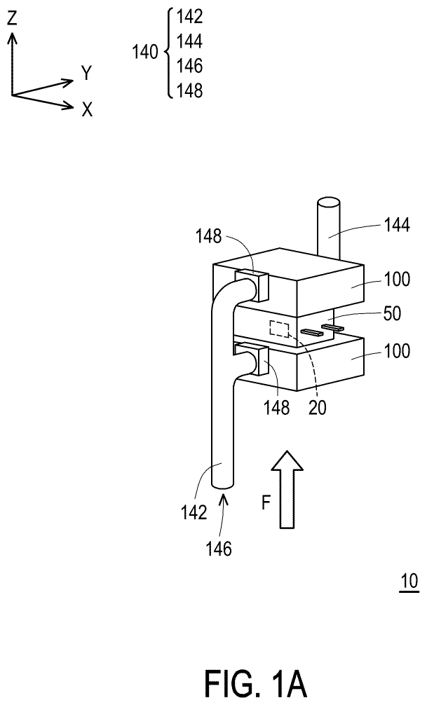

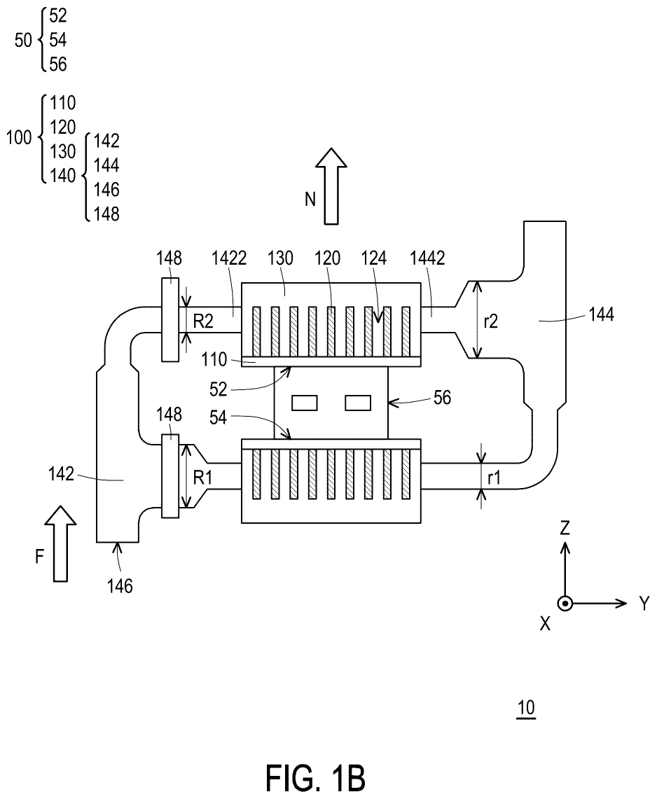

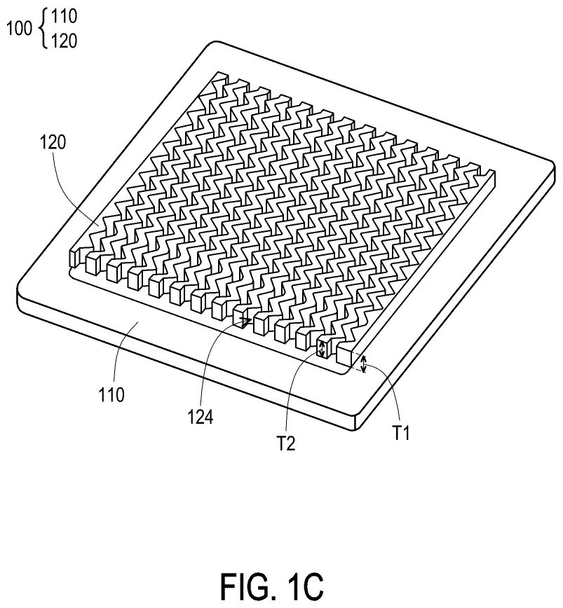

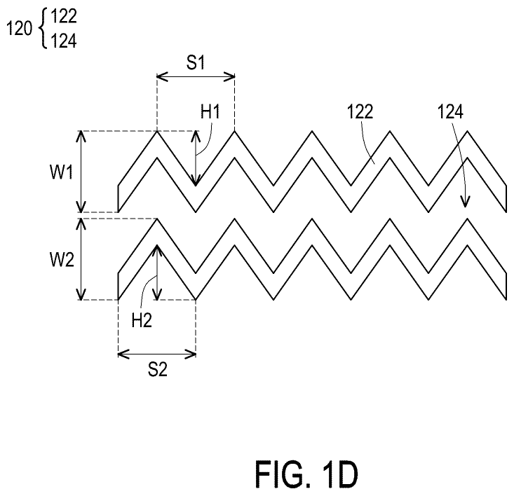

Referring to FIG. 1A to FIG. 1D at the same time, FIG. 1A is a schematic diagram of an appearance of a cooling system 10 according to a first embodiment of the disclosure. FIG. 1B is a schematic side view of the cooling system 10 of FIG. 1A. FIG. 1C is a schematic diagram of an appearance of a cooling structure 100 of FIG. 1B. FIG. 1D is a schematic top view of cooling fins 120 of FIG. 1C. It should be noted that, in order to clearly view an arrangement state of the cooling fins 120, a cover 130 in FIG. 1B is illustrated in a perspective manner, while the cover 130 is omitted in FIG. 1C.

As shown in FIG. 1A and FIG. 1B, the cooling system 10 of the embodiment may include a power module 50 and at least one cooling structure 100 (two cooling structures 100 are shown). In some embodiments, the power module 50 may be a driving module of an electric motor, or a heating element of an artificial intelligence system (for example, a central processing unit (CPU) or a graphics processing unit (GPU)), but the disclosure is not limited thereto. More specifically, the power module 50 has a top surface 52 and a bottom surface 54 opposite to each other. The two cooling structures 100 may be respectively connected to two opposite sides (i.e., the top surface 52 and the bottom surface 54) of the power module 50. In other words, the top surface 52 and the bottom surface 54 may be cooling surfaces of the power module 50. In some embodiments, the cooling structures 100 may respectively include a substrate 110 and a plurality of cooling fins 120. The plurality of cooling fins 120 may be disposed on the substrate 110, and the plurality of cooling fins 120 may form a plurality of flow channels 124.

According to the cooling system 10 of one or a plurality of embodiments of the disclosure, the two opposite sides (i.e., the top surface 52 and the bottom surface 54) of the power module 50 may be respectively cooled by the two cooling structures 100. In other words, the cooling system 10 of the embodiment may be a module that performs double side cooling (DSC) on the power module 50. More specifically, the power module 50 may perform double side cooling through the plurality of cooling fins 120 in the cooling structures 100 on both sides. In conclusion, the cooling efficiency of the cooling system 10 with an increased cooling surface area may be higher than that of a single-side cooling design, and a total thermal resistance of the power module 50 may be reduced, so that a relatively low operating temperature at high power output may be maintained to prevent overheating and reduce the formation of hotspots, thereby ensuring that the temperature of elements in the cooling system 10 is evenly distributed. At the same time, a service life of the elements in the cooling system 10 may be extended to reduce a failure rate and maintenance cost of an overall system including the cooling system 10 of the disclosure, and the stability of the overall system may be improved.

Since the cooling system 10 of the embodiment has high cooling efficiency, the power module 50 may operate at high power for a long time to improve the overall system performance. In addition, the design of the cooling system 10 may achieve a better cooling effect without significantly increasing the size of the cooling system 10. In other words, the cooling system 10 is suitable for use in designs that pursue high performance and miniaturization, and is suitable for use in devices with space limitations such as electric vehicles and artificial intelligence servers.

As shown in FIG. 1B to FIG. 1D, each of the two cooling structures 100 of the embodiment may further include a cover 130. The cover 130 may cover the substrate 110, and the cover 130 and the substrate 110 jointly accommodate the cooling fins 120. Each cooling fin 120 may have a plurality of connected wave crests 122. In some embodiments, the cooling fins 120 may be formed into a wave shape through the plurality of connected wave crests 122, but the shape of the cooling fins 120 of the disclosure is not limited thereto. It should be noted that based on the design of the cooling fins 120, when a fluid flows through the flow channel 124, the fluid is affected by the curved flow channel 124, thereby increasing a path of the fluid and achieving better cooling effect, i.e., reducing the heat generated by the power module 50. In addition, the fluid is accelerated when flowing through the curved flow channel 124, which may further enhance a convective effect and also achieve a better cooling effect, i.e., also reduce the heat generated by the power module 50.

As shown in FIG. 1C and FIG. 1D, in some embodiments, a pitch S1 between any two adjacent wave crests 122 is the same as another pitch S2 between any other two adjacent wave crests 122. In addition, heights H1 and H2 of the wave crests 122 are the same, thicknesses T1 and T2 of the cooling fins 120 are the same, and widths W1 and W2 of the cooling fins 120 are the same, so that the shapes of the flow channels 124 are the same. However, in some other embodiments, the pitches S1 and S2 between the wave crests 122 may be different from each other. The heights H1 and H2 of the wave crests 122 may be different from each other, the thicknesses T1 and T2 of the cooling fins 120 may be different from each other, and the widths W1 and W2 of the cooling fins 120 may also be different from each other, but the disclosure is not limited thereto.

In some embodiments, returning to FIG. 1A and FIG. 1B, the cooling system 10 may further include a manifold component 140 connecting the two cooling structures 100. The manifold component 140 may include an inlet branch pipe 142 and an outlet branch pipe 144. The inlet branch pipe 142 may include two inlet ports 1422 connected to the two cooling structures 100, and the two inlet ports 1422 have two inlet pipe diameters R1 and R2 of different sizes. The outlet branch pipe 144 may include two outlet ports 1442 connected to the two cooling structures 100, and the two outlet ports 1442 have two outlet pipe diameters r1 and r2 of different sizes. The fluid flows from a source 146 along an inflow direction F through the inlet branch pipe 142, the plurality of flow channels 124 of the two cooling structures 100, and the outlet branch pipe 144.

In some embodiments, the inlet branch pipe 142 and the outlet branch pipe 144 are respectively located on the other two opposite sides of the power module 50 (different from the two opposite sides of the power module 50 connected to the cooling structures 100, i.e., the opposite top surface 52 and the bottom surface 54 are illustrated along the Z-axis, but the other two opposite sides are along the X-axis). In other words, the surface of the inlet branch pipe 142 connected to the cover 130 of the cooling structure 100 and the surface of the outlet branch pipe 144 connected to the cover 130 of the cooling structure 100 are two opposite and different surfaces.

It should be noted that the inlet pipe diameter R1 corresponding to the inlet port 1422 close to the source 146 is larger than the other inlet pipe diameter R2 corresponding to the inlet port 1422 far from the source 146. The outlet pipe diameter r1 corresponding to the outlet port 1442 close to the source 146 is smaller than the other outlet pipe diameter r2 corresponding to the outlet port 1442 far from the source 146. If the pipe diameters are designed to be consistent (i.e., the inlet pipe diameters R1 and R2 are the same, and the outlet pipe diameters r1 and r2 are the same), since a flow velocity of the fluid close to the source 146 and a flow velocity of the fluid far from the source 146 are not the same, a cooling effect of the cooling structure 100 far away from the source 146 may be different from a cooling effect of the cooling structure 100 close to the source 146. Therefore, through the above-mentioned design, a pressure difference between each inlet port 1422 and the source 146 may be adjusted to make an inflow velocity of the fluid at each inlet port 1422 the same, thereby making the cooling effect of each cooling structure 100 consistent. In addition, overall power consumption of a motor (not shown) used for transporting the fluid may also be reduced to achieve an energy saving effect.

In some embodiments, the cooling system 10 may further include a temperature sensor 20 located in the power module 50, and the manifold component 140 may further include two valve body components 148 respectively disposed at the two inlet ports 1422. In some embodiments, the two valve body components 148 may also be disposed at the two outlet ports 1442. The temperature sensor 20 may detect a temperature of the power module 50 at any time. In some embodiments, the valve body component 148 may be a thermocouple temperature sensor (TC sensor), and the valve body component 148 may also include a solenoid valve (not shown), a pressure sensor (not shown), and/or a flow meter (not shown), but the disclosure is not limited thereto. The flow meter mentioned above may be a Hall sensor, and the flow meter may be used to sense a pressure value of the fluid flowing through the inlet port 1422 to deduce a flow velocity of the fluid there.

More specifically, the temperature sensor 20 may detect temperatures of the power module 50 at various time points to obtain temperature data, and may transmit the temperature data to an artificial intelligence system (not shown) to analyze and determine whether the temperature of the power module 50 is abnormal. In some embodiments, if the temperature of the power module 50 is abnormal, the artificial intelligence system may adjust a flow rate of the fluid flowing through the valve body component 148, thereby adjusting the cooling efficiency of the cooling structure 100 for the power module 50. For example, when the temperature of the power module 50 rises rapidly and the original cooling structure 100 cannot quickly dissipate the heat, the artificial intelligence system may determine that the temperature of the power module 50 is unstable and abnormal. After determining the aforementioned abnormality, the artificial intelligence system adjusts the solenoid valve of the valve body component 148 corresponding to the cooling structure 100 to automatically adjust the flow rate of the fluid flowing through the cooling structure 100, thereby improving the cooling efficiency of the cooling structure 100. Through the above-mentioned design, the temperature of the power module 50 may be precisely controlled, thereby ensuring temperature stability of the power module 50.

Based on one or more of the aforementioned embodiments, the cooling system 10 may use the manifold component 140 to connect the cooling structures 100. Through the above-mentioned design, the structure of the overall cooling system 10 may be made more flexible and applicable to multi-channel cooling requirements. In addition, the cooling system 10 may adjust the temperature of each cooling structure 100 at any time through the adjustment of the pipe diameters and the combination of the valve body components 148, the temperature sensor 20 and/or the artificial intelligence system, so as to stably maintain the temperature of the power devices (not shown) inside the power module 50 at the optimal operating temperature.

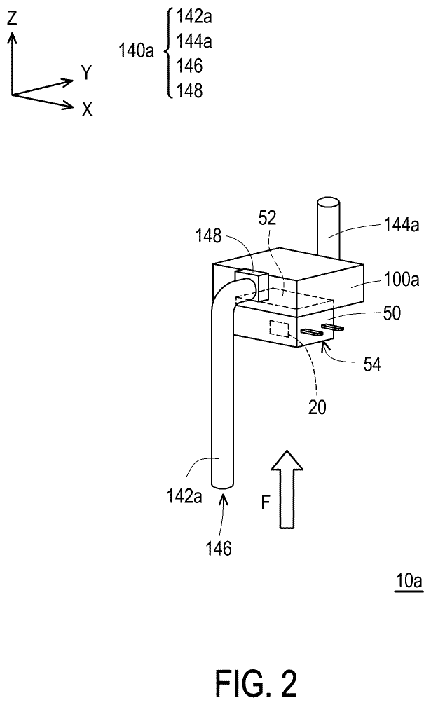

Referring to FIG. 2, FIG. 2 is a schematic diagram of an appearance of a cooling system 10a according to a second embodiment of the disclosure. In some embodiments, the cooling system 10a is similar to the cooling system 10 of the first embodiment in FIG. 1A and FIG. 1B. It should be noted that a difference between the two embodiments is that the cooling system 10a of the embodiment has only one cooling structure 100a connected to the top surface 52 of the power module 50, and the inlet branch pipe 142a and the outlet branch pipe 144a of the manifold component 140a are only connected to the aforementioned cooling structure 100a. In some embodiments, the cooling structure 100a may also be only connected to the bottom surface 54 of the power module 50. In other words, the power module 50 may also dissipate heat through only one cooling structure 100a. More specifically, the temperature sensor 20 detects the temperature data of the power module 50 at various time points and transmits the same to an artificial intelligence system (not shown) to analyze and determine whether the temperature of the power module 50 is abnormal. In the embodiment, if the temperature of the power module 50 is abnormal, the artificial intelligence system may adjust the flow rate of the fluid flowing through the valve body component 148, thereby adjusting the cooling efficiency of the cooling structure 100a for the power module 50. Compared with the double side cooling of FIG. 1A, the cooling system 10a may also automatically adjust the flow rate of the fluid flowing through the cooling structure 100a to improve the cooling efficiency of the cooling structure 100a.

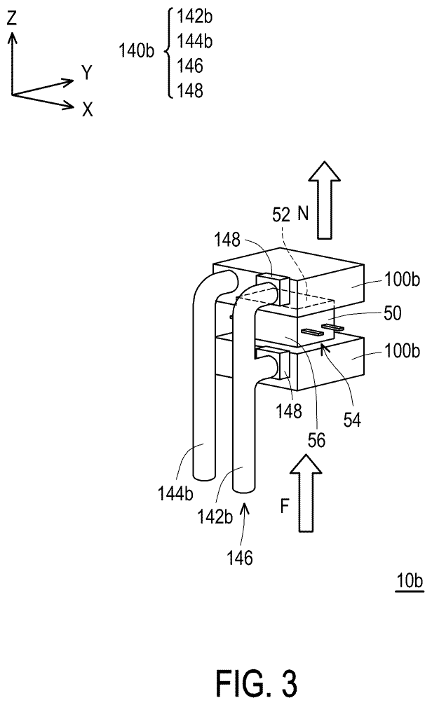

Referring to FIG. 3, FIG. 3 is a schematic diagram of an appearance of a cooling system 10b according to a third embodiment of the disclosure. In some embodiments, the cooling system 10b is similar to the cooling system 10 of the first embodiment in FIG. 1A and FIG. 1B. It is should be noted that a difference between the two embodiments is that the inlet branch pipe 142b and the outlet branch pipe 144b of the manifold component 140b of the cooling system 10b of the embodiment are located on a same side of the power module 50 (also located on the same side of the cooling structure 100b). In other words, if the inlet branch pipe 142b is projected onto a side surface 56 of the power module 50, it is the same side surface 56 as the side surface 56 where the outlet branch pipe 144b is projected onto the power module 50. According to the above design, the inlet branch pipe 142b and the outlet branch pipe 144b on the same side may reduce a volume of the cooling system 10b in a lateral direction (for example, the Y-axis direction of FIG. 2), so as to further improve a space utilization of the cooling system 10b, and achieve a compact pipeline design of the cooling system 10b, but the pipeline design method of the disclosure is not limited thereto, please refer to the following for further details.

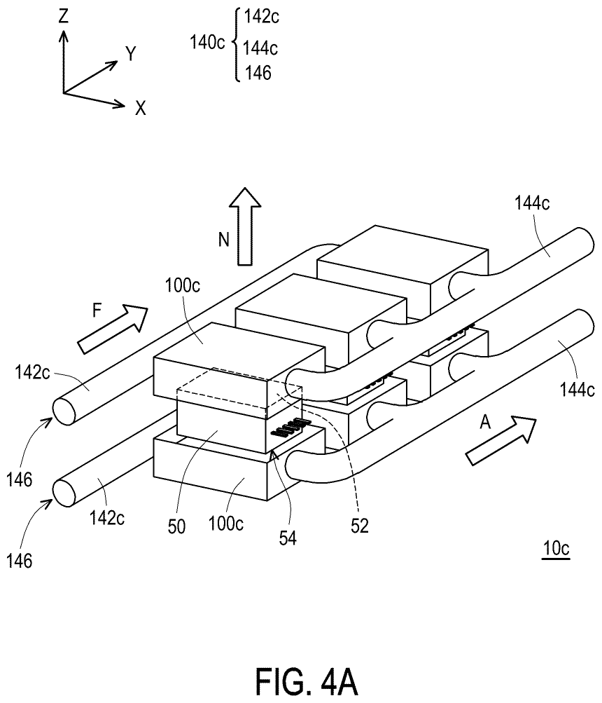

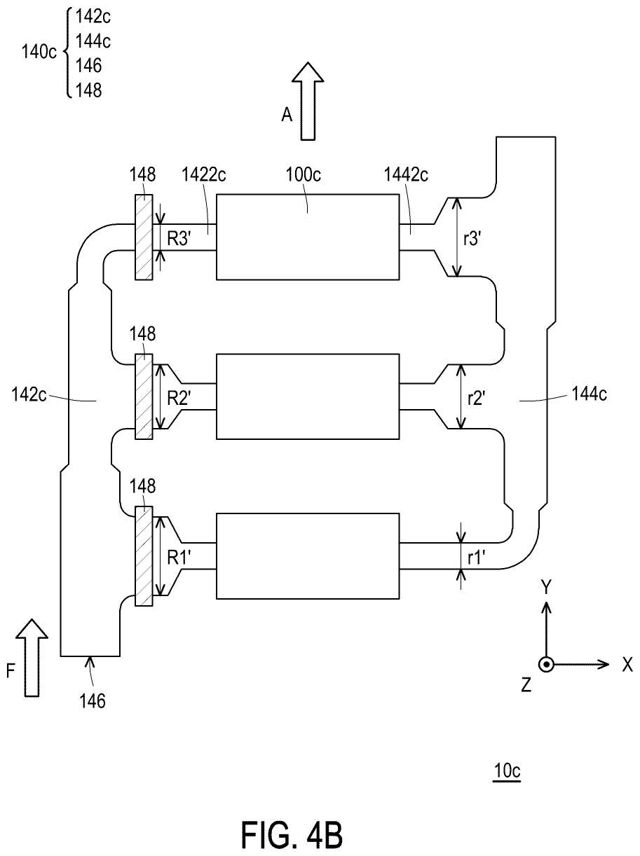

Referring to FIG. 4A and FIG. 4B at the same time, FIG. 4A is a schematic diagram of an appearance of a cooling system 10c according to a fourth embodiment of the disclosure. FIG. 4B is a schematic top view of the cooling system 10c in FIG. 4A. In some embodiments, the cooling system 10c is similar to the cooling system 10 in FIG. 1A and FIG. 1B. It should be noted that a difference between the two embodiments is that the cooling system 10c of the embodiment has at least two power modules 50 (three power modules 50 are shown), a plurality of cooling structures 100c, two inlet branch pipes 142c, two outlet branch pipes 144c, and a plurality of correspondingly arranged valve body components 148.

In some embodiments, the power modules 50 of the cooling system 10c may be three-phase structure power modules 50, but the disclosure is not limited thereto. As shown in FIG. 4A, the plurality of power modules 50 are arranged along an arrangement direction A, and the arrangement direction A is perpendicular to a normal direction N of the top surface 52. In other words, the plurality of power modules 50 are arranged on the same plane and may be arranged in a straight line along the arrangement direction A, but the disclosure is not limited thereto.

Referring to FIG. 1B, FIG. 4A, and FIG. 4B at the same time, the two opposite sides of each power module 50 (for example, the top surface 52 and the bottom surface 54 of FIG. 1B) may all be connected to the cooling structures 100c for cooling. In other words, the cooling system 10c of the embodiment may also be a module that is adapted to perform double side cooling on the power modules 50. The detailed structure and effects of the cooling structure 100c may be referred to the aforementioned embodiments, which will not be repeated here.

Referring to FIG. 4A, the manifold component 140c of the embodiment may include two inlet branch pipes 142c and two outlet branch pipes 144c connected to the plurality of cooling structures 100c. In some embodiments, one of the two inlet branch pipes 142c and one of the two corresponding outlet branch pipes 144c may be connected to the cooling structure 100c for dissipating heat from the top surface 52 of the power module 50, and another inlet branch pipe 142c and another corresponding outlet branch pipe 144c may be connected to the cooling structure 100c for cooling from the bottom surface 54 of the power module 50.

In addition, the two inlet branch pipes 142c are located on one side of the power modules 50 (for example, the left side of FIG. 4A and FIG. 4B), and the two outlet branch pipes 144c are located on the other side of the power modules 50 (for example, the right side of FIG. 4A and FIG. 4B). In some embodiments, the two inlet branch pipes 142c have corresponding two sources 146. In some other embodiments, the two inlet branch pipes 142c may also be connected to the same source 146. In other embodiments, the number of the inlet branch pipes 142c and the number of the outlet branch pipes 144c may also be adjusted according to actual needs, which are not limited by the disclosure.

More specifically, the inlet branch pipe 142c may include a plurality of inlet ports 1422c connected to the cooling structures 100c, and the outlet branch pipe 144c may include a plurality of outlet ports 1442c connected to the cooling structures 100c. It should be noted that the plurality of inlet ports 1422c may have a plurality of inlet pipe diameters R1′, R2′, R3′ of different sizes, and the plurality of inlet pipe diameters R1′, R2′, R3′ of the plurality of inlet ports 1422c decrease along with increase of a distance from the source 146. In addition, the plurality of outlet ports 1442c may have a plurality of outlet pipe diameters r1′, r2′, r3′ of different sizes, and the plurality of outlet pipe diameters r1′, r2′, r3′ of the plurality of outlet ports 1442c increase along with increase of a distance from the source 146. Specifically, the inlet pipe diameter R1′ is larger than the inlet pipe diameter R2′. The inlet pipe diameter R2′ is larger than the inlet pipe diameter R3′. The outlet pipe diameter r1′ is smaller than the outlet pipe diameter r2′. The outlet pipe diameter r2′ is smaller than the outlet pipe diameter r3′. In summary, the aforementioned tube diameter design may make the cooling effect of each cooling structure 100c consistent. The overall power consumption of the motor (not shown) for transporting the fluid may also be reduced accordingly, thereby achieving the energy saving effects.

TABLE ONE

| Flow | | Pressure | Pressure difference |
|---|---|---|---|
| rate | Corresponding position | (Pa) | (Pa) |
| 7 L/min | Inlet pipe diameter R1′ | 114960 | 13236 |
| | Outlet pipe diameter r1′ | 101724 | |
| | Inlet pipe diameter R2′ | 115194 | 13540 |
| | Outlet pipe diameter r2′ | 101654 | |
| | Inlet pipe diameter R3′ | 115154 | 13591 |
| | Outlet pipe diameter r3′ | 101563 | |
| 2.4 L/min | Inlet pipe diameter R1′ | 103284 | 1907 |
| | Outlet pipe diameter r1′ | 101377 | |
| | Inlet pipe diameter R2′ | 103310 | 1942 |
| | Outlet pipe diameter r2′ | 101368 | |
| | Inlet pipe diameter R3′ | 103307 | 1952 |
| | Outlet pipe diameter r3′ | 101355 | |

More specifically, referring to Table 1, experimental results are shown as above. When the inlet pipe diameter R1′, the inlet pipe diameter R2′, and the inlet pipe diameter R3′ are respectively designed to be 16 cm, 14 cm, and 12 cm, and the outlet pipe diameter r1′, the outlet pipe diameter r2′, and the outlet pipe diameter r3′ are respectively designed to be 12 cm, 14 cm, and 16 cm, the pressure difference will be similar regardless of the flow velocity, so that the flow rates flowing through the three inlet ports 1422c are uniform, and the cooling effect of each cooling structure 100c is consistent.

In some embodiments, the manifold component 140c may include a plurality of valve body components 148 disposed at the plurality of inlet ports 1422c. In some other embodiments, each power module 50 may further include a temperature sensor 20. As mentioned above, through the cooperation of multiple temperature sensors 20 (as shown in FIG. 1A), an artificial intelligence system (not shown), and multiple valve body components 148, the cooling efficiency of each cooling structure 100c may be further adjusted. More specifically, by adjusting the cooling efficiency of the cooling structure 100c, the temperature of each power module 50 may be adjusted according to a required temperature. For example, allowable upper temperature limits of each of the power modules 50 are different, and different states of the valve body component 148 may be set according to the allowable upper temperature limits of each power module 50 to achieve different temperature states of each power module 50. In other words, through the above-mentioned design, the cooling efficiency of each cooling structure 100c may be adjusted according to the state, the required temperature and other factors of each power module 50, so as to achieve better temperature control.

It should be added that although the cooling system 10c of the embodiment is illustrated as having three power modules 50, the number of the power modules 50 may also be designed according to actual needs, and the number of the inlet ports 1422c of the inlet branch pipe 142c and the number of the outlet ports 1442c of the outlet branch pipe 144c may also be adjusted accordingly. Certainly, the sizes of the inlet pipe diameters R1′, R2′, R3′ and the outlet pipe diameters r1′, r2′, r3′ may also be adjusted accordingly according to the aforementioned manner. In other words, the manifold component 140c may make the structure of the cooling system 10c more flexible and suitable for multi-channel cooling requirements.

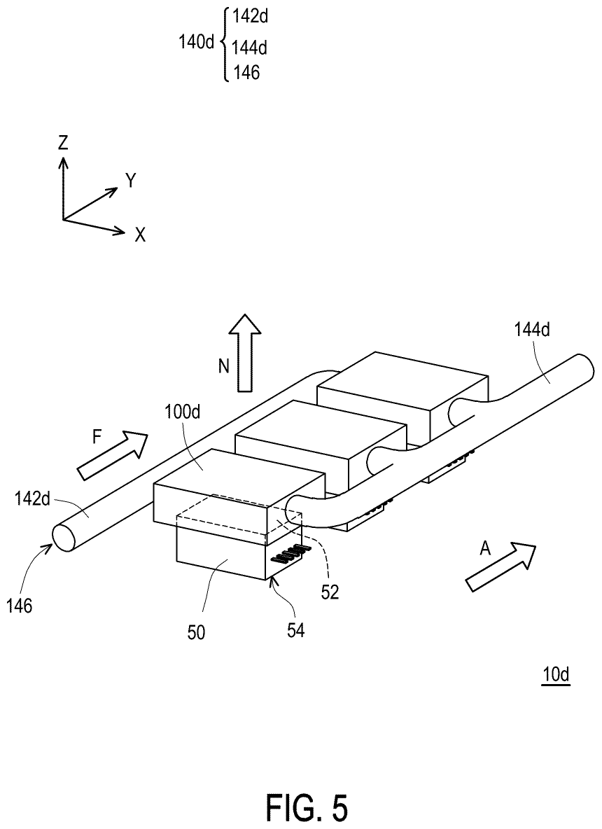

Referring to FIG. 5, FIG. 5 is a schematic diagram of an appearance of a cooling system 10d according to a fifth embodiment of the disclosure. In some embodiments, the cooling system 10d is similar to the cooling system 10c in FIG. 4A and FIG. 4B. It should be noted that a difference between the two embodiments is that a plurality of cooling structures 100d of the cooling system 10d of the embodiment are all connected to the top surfaces 52 of the power modules 50, while the manifold component 140d only includes one inlet branch pipe 142d and one outlet branch pipe 144d. In some embodiments, the cooling structures 100d may also be connected only to the bottom surfaces 54 of the power modules 50. In other words, the cooling structures 100d are all located on a same plane. Through the above design, each power module 50 may not only dissipate heat through one cooling structure 100d, but may also reduce a volume of the cooling system 10d in a vertical direction (for example, the Z-axis direction of FIG. 5), thereby further improving a space utilization rate of the cooling system 10d.

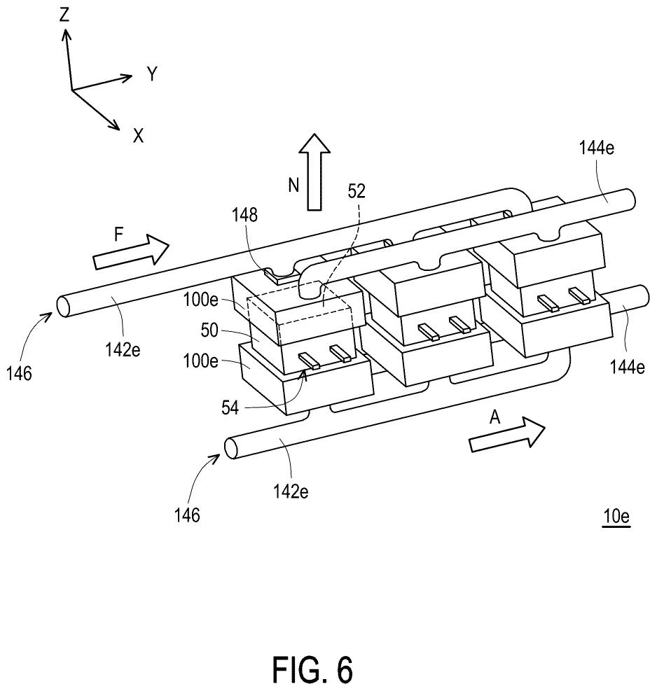

Referring to FIG. 6, FIG. 6 is a schematic diagram of an appearance of a cooling system 10e according to a sixth embodiment of the disclosure. In some embodiments, the cooling system 10e is similar to the cooling system 10c in FIG. 4A and FIG. 4B. It should be noted that a difference between the two embodiments is that one inlet branch pipe 142e and one corresponding outlet branch pipe 144e of a manifold component 140e of the cooling system 10e of the embodiment are located on one side of the power modules 50 (for example: located above the top surfaces 52 of the power modules 50), and are connected to the cooling structure 100e of the same portion. Another inlet branch pipe 142e and another corresponding outlet branch pipe 144e are located at the other side of the power modules 50 (for example, located below the bottom surfaces 54 of the power modules 50) and are connected to the cooling structure 100e of another same portion. According to the above design, a volume of the cooling system 10e in a longitudinal direction (for example, the X-axis direction of FIG. 6) may be reduced to further improve the space utilization rate of the cooling system 10e.

It should be noted that, in other embodiments, the two inlet branch pipes 142e and the two outlet branch pipes 144e may also be disposed on the same side of the power modules 50 (for example, located on the left side or the right side of the power modules 50 at the same time), but the disclosure is not limited thereto.

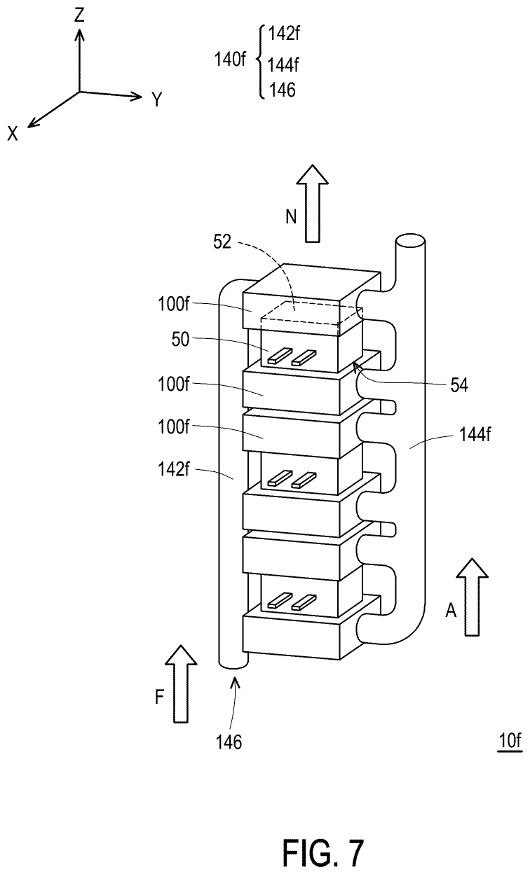

Referring to FIG. 7, FIG. 7 is a schematic diagram of an appearance of a cooling system 10f according to a seventh embodiment of the disclosure. In some embodiments, the cooling system 10f is similar to the cooling system 10c in FIG. 4A and FIG. 4B. It should be noted that a difference between the two embodiments is that the cooling structures 100f and the power modules 50 of the cooling system 10f of the embodiment are all arranged along an arrangement direction A, and the arrangement direction A is parallel to a normal direction N of the top surface 52. In addition, the manifold component 140f includes only one inlet branch pipe 142f and one outlet branch pipe 144f.

More specifically, the cooling structures 100f and the power modules 50 are arranged in a straight line along the arrangement direction A. The inlet branch pipe 142f and the outlet branch pipe 144f connect all of the cooling structures 100f, and the inlet branch pipe 142f and the outlet branch pipe 144f are located on the other two opposite sides of the power modules 50 (for example, located on the left and right sides of the power modules 50 of FIG. 7). According to the above design, the inlet branch pipe 142f and the outlet branch pipe 144f on the two opposite sides may reduce a volume of the cooling system 10f in a lateral direction (for example, the Y-axis direction of FIG. 7), and make the volume of the cooling system 10f to extend mainly in the vertical direction (for example, the Z-axis direction of FIG. 7), thereby improving the space utilization rate of the cooling system 10f.

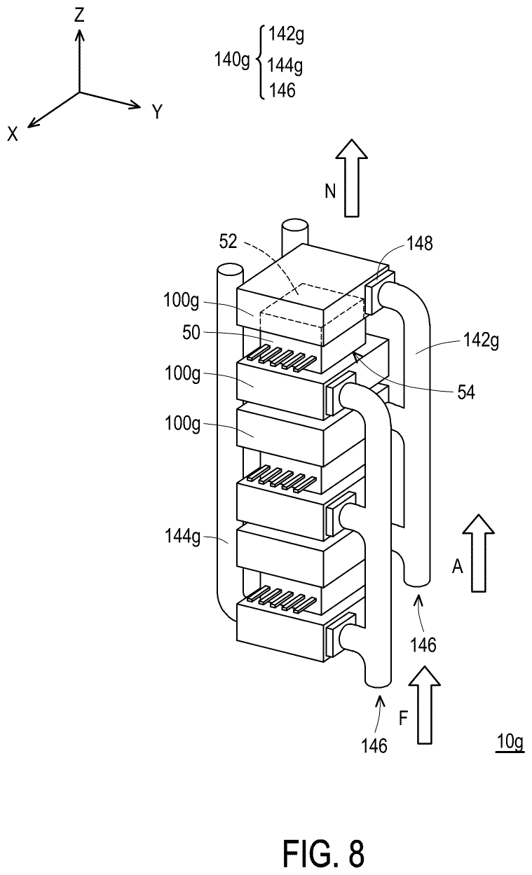

Referring to FIG. 8, FIG. 8 is a schematic diagram of an appearance of a cooling system 10g according to an eighth embodiment of the disclosure. In some embodiments, the cooling system 10g is similar to the cooling system 10f in FIG. 7. It should be noted that a difference between the two embodiments is that the cooling system 10g of the embodiment has two inlet branch pipes 142g and two corresponding outlet branch pipes 144g of the manifold components 140g connected to different cooling structures 100g.

It should be noted that, although FIG. 8 only shows two inlet branch pipes 142g and two corresponding outlet branch pipes 144g, in other embodiments, more inlet branch pipes 142g and outlet branch pipes 144g may be included, which is not limited by the disclosure.

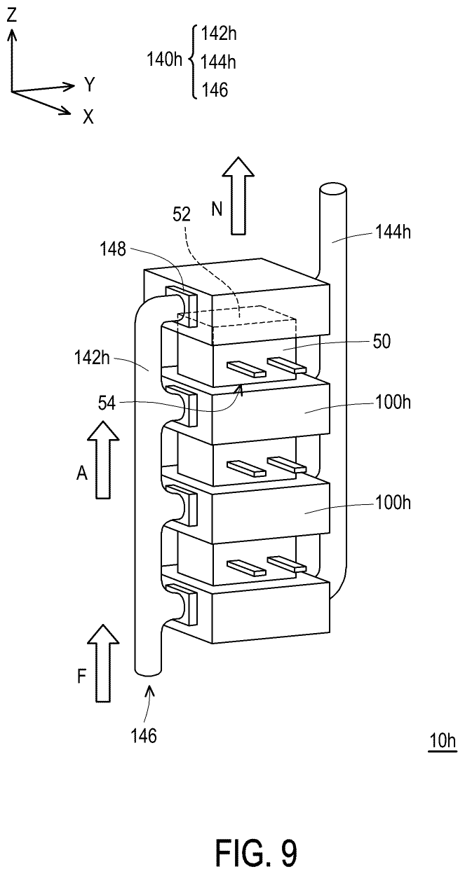

Referring to FIG. 9, FIG. 9 is a schematic diagram of an appearance of a cooling system 10h according to a ninth embodiment of the disclosure. In some embodiments, the cooling system 10h is similar to the cooling system 10f in FIG. 7. It should be noted that a difference between the two embodiments is that any two adjacent power modules 50 of the cooling system 10h of the embodiment are connected to the same cooling structure 100h. In other words, two adjacent power modules 50 may share one same cooling structure 100h for cooling. According to the above design, not only a volume of the cooling system 10h in the vertical direction (for example, the Z-axis direction in FIG. 9) may be reduced, but also a weight of the entire cooling system 10h may be greatly reduced. In addition, lengths of the inlet branch pipe 142h and the outlet branch pipe 144h of the manifold component 140h (for example, the lengths extending in the Z-axis direction of FIG. 9) may also be reduced. In other words, according to the above design, the manufacturing cost of the overall cooling system 10h may be reduced.

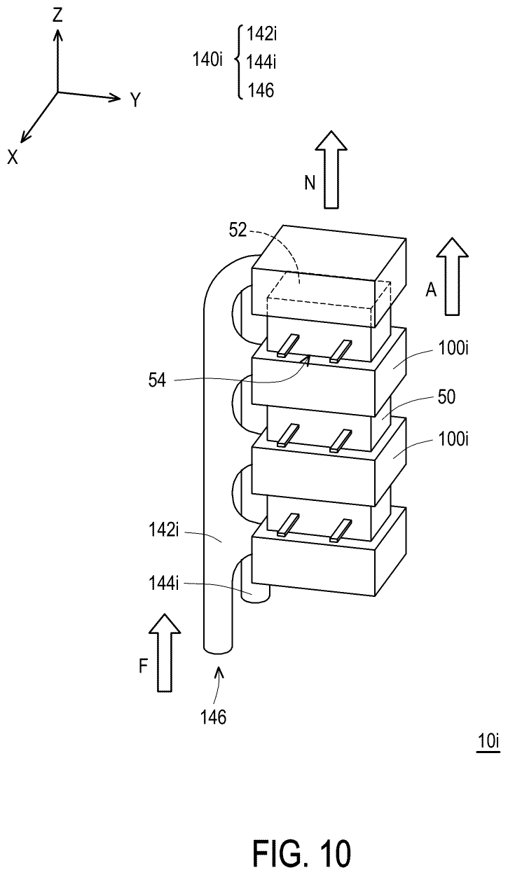

Referring to FIG. 10, FIG. 10 is a schematic diagram of an appearance of a cooling system 10i according to a tenth embodiment of the disclosure. In some embodiments, the cooling system 10i is similar to the cooling system 10h in FIG. 9. It should be noted that a difference between the two embodiments is that an inlet branch pipe 142i and an outlet branch pipe 144i of a manifold component 140i of the cooling system 10i of the embodiment are located on a same side of the power modules 50 (also located on a same side of the cooling structure 100i). According to the above design, the inlet branch pipe 142i and the outlet branch pipe 144i on the same side may further reduce a volume of the cooling system 10i in the lateral direction (for example, the Y-axis direction of FIG. 10), so as to further increase a space utilization rate of the cooling system 10i.

The following is a supplementary analysis of flow distribution characteristics of one of the multi-branch cooling systems 10-10i, especially changes in fluid flow velocity, pressure loss and flow distribution when designs of each of the branch pipe diameters are inconsistent. The following description will first be made by taking the cooling system 10c shown in FIG. 4A and FIG. 4B as an example. A coolant flows from the source 146 into the inlet branch pipe 142c of the manifold component 140c of the cooling system 10c, and then the coolant is distributed to the three inlet ports 1422c and flows into the corresponding cooling structures 100c, and then flows out through the outlet port 1442c of the corresponding outlet branch pipe 144c. In order to test the effect of the difference in inlet pipe diameters R1′, R2′, and R3′ on flow distribution, the inlet pipe diameters R1′, R2′, and R3′ are designed to be 12 cm for the inlet pipe diameter R3′, 14 cm for the inlet pipe diameter R2′, and 16 cm for the inlet pipe diameter R1′. A Darcy-Weisbach equation related to pressure loss, inlet/outlet pipe diameter, friction coefficient, flow velocity and fluid density, etc., is shown as a following equation (1), a continuity equation related to flow velocity is shown as a following equation (2), and a cross-sectional area related equation is shown as a following equation (3):

$$Δ P = f \times ( \frac{L}{d} ) \times ( ρ \times \frac{{v}^{2}}{2} ) \qquad equation ( 1 )$$

$$Q = A \times v \qquad equation ( 2 )$$

$$A = π \times {( \frac{d}{2} )}^{2} \qquad equation ( 3 )$$

Based on the above, the above equation (1) is the Darcy-Weisbach equation, which describes a pressure loss ΔP as being related to a pipe diameter d, a friction coefficient f, a flow velocity v and a fluid density ρ; while the above equation (2) is the content of calculating the flow velocity v based on the continuity equation. In addition, the above equation (3) describes that a cross-sectional area A relates to the pipe diameter d, where the pipe diameter d may be the inlet pipe diameters R1′, R2′, R3′. For example, a total flow rate of the fluid is set to 2.4 L/min (0.00004 m³/s) and the fluid is evenly divided into the three inlet ports 1422c. Through data calculation, a coolant flow velocity corresponding to the inlet pipe diameter R3′ may be 0.001179 m/s, and the pressure loss may be 0.000006 Pa; the coolant flow velocity corresponding to the inlet pipe diameter R2′ may be 0.000866 m/s, and the pressure loss may be 0.000003 Pa. In addition, the coolant flow velocity corresponding to the inlet pipe diameter R1′ may be 0.000663 m/s, and the pressure loss may be 0.000001 Pa.

It should be noted that in some other embodiments, in the case that the outlet pipe diameters r1′, r2′, and r3′ are not adjusted, the larger the inlet pipe diameters R1′, R2′, and R3′ are, the lower the flow velocity is, and the smaller the pressure loss is. In particular, the pressure loss of the inlet port 1422c corresponding to the inlet pipe diameter R1′ is the lowest, and the fluid may naturally tend to flow into the inlet port 1422c with smaller pressure loss, thereby causing an increase in the flow rate at the inlet port 1422c. The inlet pipe diameter R3′ of the inlet port 1422c corresponding to the inlet pipe diameter R3′ is the smallest, the flow velocity is the highest, and the corresponding pressure loss is the largest, so that the flow rate is relatively small. More specifically, in the aforementioned situation, the flow rates flowing through the three inlet ports 1422c are unevenly distributed, and the coolant is more inclined to the inlet port 1422c with lower pressure loss, which often leads to an uneven cooling effect.

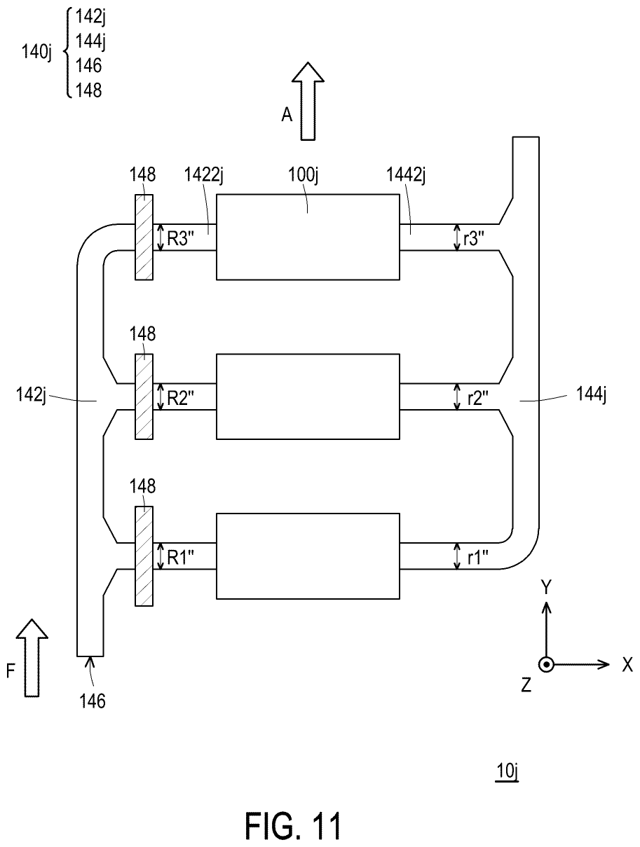

In addition, please refer to FIG. 11, FIG. 11 is a schematic top view of a cooling system 10j according to an eleventh embodiment of the disclosure. In some embodiments, the cooling system 10j is similar to the cooling system 10c in FIG. 4B. It should be noted that a difference between the two embodiments is that the three inlet pipe diameters R1″, R2″, and R3″ of the inlet ports 1422j of the inlet branch pipe 142j of the manifold component 140j of the embodiment are the same as each other, and the three outlet pipe diameters r1″, r2″, and r3″ of the outlet ports 1442j of the outlet branch pipe 144j are the same as each other.

TABLE TWO

| Flow | | Pressure | Pressure difference |
|---|---|---|---|
| rate | Corresponding position | (Pa) | (Pa) |
| 7 L/min | Inlet pipe diameter R1″ | 116678 | 13726 |
| | Outlet pipe diameter r1″ | 102952 | |
| | Inlet pipe diameter R2″ | 116857 | 14035 |
| | Outlet pipe diameter r2″ | 102822 | |
| | Inlet pipe diameter R3″ | 116896 | 14623 |
| | Outlet pipe diameter r3″ | 102273 | |
| 2.4 L/min | Inlet pipe diameter R1″ | 103565 | 2034 |
| | Outlet pipe diameter r1″ | 101531 | |
| | Inlet pipe diameter R2″ | 103592 | 2080 |
| | Outlet pipe diameter r2″ | 101512 | |
| | Inlet pipe diameter R3″ | 103591 | 2149 |
| | Outlet pipe diameter r3″ | 101442 | |

More specifically, referring to the Table two, the experimental results are shown as above, when the inlet pipe diameter R1″, the inlet pipe diameter R2″, and the inlet pipe diameter R3″ are, for example, all 12 cm, and the outlet pipe diameter r1″, the outlet pipe diameter r2″, and the outlet pipe diameter r3″ are, for example, all 12 cm, regardless of the flow velocity, the pressure differences between the three inlet ports 1422j and the corresponding three outlet ports 1442j are different from each other, resulting in uneven flow rates flowing through the three inlet ports 1422j and uneven cooling effects of each of the cooling structures 100j.

It should be noted that by comparing the above Table 1 with Table 2, regarding the cooling systems 10c and 10j with the manifold components 140c and 140j of different branch pipe diameters, under conditions of different flow rates, the pressure differences between the inlet ports 1422c, 1422j and the outlet ports 1442c, 1442j of each of the cooling systems 10c and 10j are shown. The results in Table 1 are all lower than those in Table 2 for the manifold components 140c and 140j with the same branch pipe diameter, indicating that by using the design of manifold components 140c and 140j with different branch pipe diameters, the overall power consumption for transporting the fluid (for example, the power consumption of the motor) may be reduced accordingly, thereby achieving the energy saving effects.

In order to solve the above-mentioned problems, the disclosure may further combine with an artificial intelligence system to install adjustable valve body components 148 at each of the inlet ports 1422c and 1422j (or the outlet ports 1442c and 1442j), by using a pressure sensor (not shown) and a flow meter (not shown) to implement real-time monitoring, a pressure loss and flow data of each of the inlet ports 1422c and 1422j are calculated by using an algorithm of the artificial intelligence system to dynamically adjust an opening and closing degree or opening and closing frequency of a solenoid valve (not shown) to balance the pressure loss, and finally realizes a balanced distribution of the flow rate at the three inlet ports 1422c and 1422j. In other words, by adjusting the valve body components 148 through the artificial intelligence system, the pressure difference before and after the fluid flows through each of the cooling systems 10c and 10j may be reduced, so that the flow rates through the three inlet ports 1422c and 1422j are uniform, thereby making each of the cooling structures 100c and 100j to have the balanced cooling effects. The overall power consumption of the motor (not shown) for transporting the fluid may also be reduced accordingly, thereby achieving the energy saving effects. In addition, the cooling systems 10c and 10j may be automatically optimized and adjusted according to actual conditions, such as changes in friction coefficient, differences in pipe length, fluid viscosity, etc., to ensure that the cooling systems operate stably and efficiently.

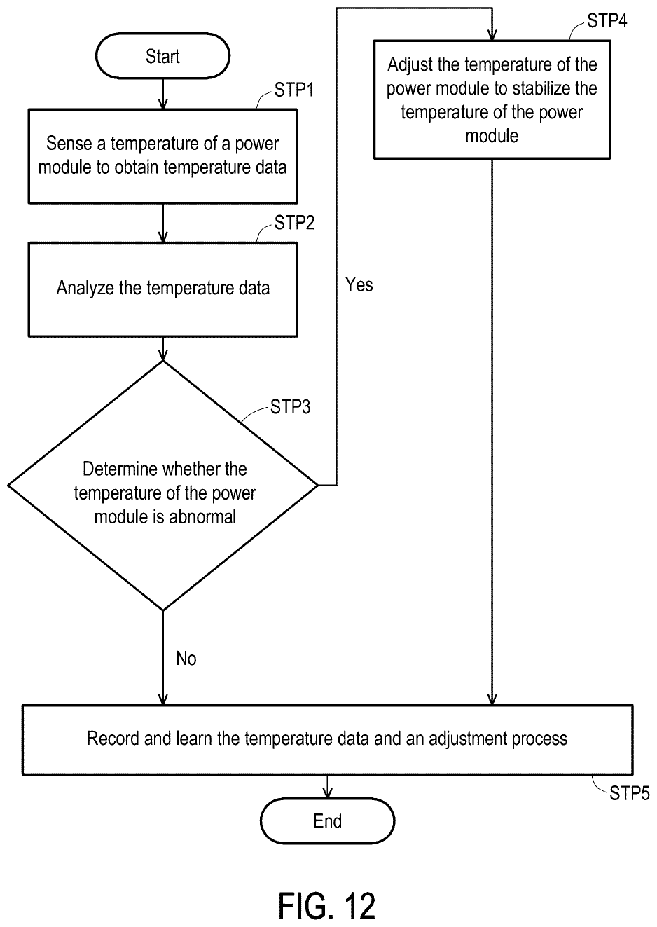

Referring to FIG. 1A, FIG. 1B and FIG. 12 simultaneously, FIG. 12 is a schematic flowchart of a control method of the cooling systems 10-10j of the disclosure. The control method of the cooling systems 10-10j of the disclosure is described below. First, referring to step STP1, a temperature of the power module 50 is sensed to obtain temperature data. More specifically, the temperature of at least one power module 50 may be sensed by at least one temperature sensor 20 (as shown in FIG. 1A) to obtain at least one temperature data. Then, referring to step STP2, the temperature data is analyzed. More specifically, the at least one temperature data may be analyzed through an artificial intelligence system. Further, referring to step STP3, it is determined whether the temperature of the power module 50 is abnormal. More specifically, the aforementioned artificial intelligence system may be used to determine whether the temperature of any one of the at least one power modules 50 is abnormal.

When the artificial intelligence system determines that the temperature of the power module 50 is abnormal, the process proceeds to step STP4, and the temperature of the power module 50 is adjusted to stabilize the temperature of the power module 50. More specifically, when the artificial intelligence system determines that the temperature of the power module 50 is abnormal, the artificial intelligence system may be used to adjust the temperature of the power module 50 with the abnormal temperature so that the temperature of the power module 50 may return to normal. On the contrary, when the artificial intelligence system determines that the temperature of the power module 50 is normal, or the abnormal temperature of the power module 50 has been stabilized, the process proceeds to step STP5, and the above temperature data and adjustment process are recorded and learned. More specifically, when the artificial intelligence system determines that the temperature of the power module 50 is no longer abnormal, the artificial intelligence system may be used to record and learn the temperature data and/or adjustment process.

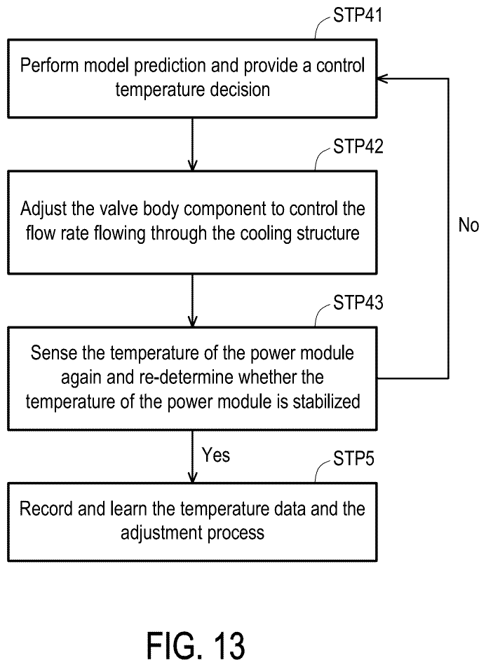

Referring to FIG. 1A, FIG. 1B and FIG. 13 simultaneously, FIG. 13 is a detailed flowchart of the control method of FIG. 12. Furthermore, when the artificial intelligence system determines that the temperature of the power module 50 is abnormal and continues to adjust the temperature of the power module 50 in step STP4, the process may be further divided into steps STP41 to STP43. In step STP41, the artificial intelligence system may be used to perform model prediction and provide a control temperature decision. Then, in step STP42, the valve body component 148 is adjusted to control the flow rate flowing through the cooling structures 100-100j. More specifically, the artificial intelligence system may adjust the solenoid valve of at least one valve body component 148 according to the temperature decision, thereby adjusting the flow rate of the fluid flowing through the inlet branch pipes 142-142j. More specifically, in step STP42, the artificial intelligence system may also adjust the flow rate flowing through the cooling structures 100-100j by adjusting the solenoid valve of the valve body component 148. After the solenoid valve of the valve body component 148 is adjusted, the process proceeds to step STP43, and the temperature of the power module 50 is sensed again and it is re-determined whether the temperature of the power module 50 is stabilized. More specifically, the temperature of the power module 50 may be sensed again by the temperature sensor 20 to obtain at least one new temperature data, and the new temperature data may be analyzed by the artificial intelligence system to determine whether the temperature of any of the power modules 50 has been stabilized. If the temperature is stabilized, the process proceeds to step STP5. On the contrary, if the temperature does not return to normal, the process returns to step STP41 to re-execute the temperature adjustment.

Through one or more of the aforementioned implementation methods, the disclosure may monitor whether an operating status of the power module 50 is normal at any time through the temperature sensor 20, the valve body component 148, and the artificial intelligence system. In addition, the artificial intelligence system repeatedly records the temperature and learns the entire adjustment process, so that the temperature control of the power module 50 of the cooling systems 10-10j may be optimized to achieve precise cooling management. More specifically, the artificial intelligence system may predict and determine a potential problem based on previously recorded temperature data, so that before the problem occurs (for example, the temperature of the power module 50 rises sharply), the artificial intelligence system may provide the control temperature decision in advance, so as to avoid occurrence of the above problem in advance, thereby ensuring operation continuity and efficiency of the entire cooling systems 10-10j.

In summary, through one or more embodiments of the disclosure, the top surface or the bottom surface of the power module may be connected to the cooling structure. It should be noted that the cooling system and control method thereof of one or more embodiments of the disclosure further adopt a double side cooling design to increase a cooling surface area, which may effectively improve the cooling efficiency, extend element service life, and improve the stability of the overall system.

Through one or more embodiments of the disclosure, the cooling fins of the cooling structure may also have a plurality of connected wave crests to form a wave shape, so that the fluid may quickly take away the heat of the power module. Furthermore, the pipe diameters at each inlet port and each outlet port of the disclosure are adjusted according to the distances from the source, so that the cooling effect of each cooling structure may be consistent. In addition, in one or more embodiments of the disclosure, the temperature of each cooling structure may be adjusted at any time through the cooperation of the valve body components, the temperature sensor, and the artificial intelligence system, so that the temperature of the power module is maintained at the optimal operating temperature, and the pressure difference before and after the fluid flows through each cooling system may be reduced, thereby reducing the overall power consumption of the motor that transports the fluid, and achieve the energy saving effects.

What is claimed is:

1. A cooling system, comprising:
a power module, having a top surface and a bottom surface opposite to each other; and
at least one cooling structure, wherein at least one of the top surface or the bottom surface of the power module is connected to the at least one cooling structure, each of the at least one cooling structure comprises a substrate and a plurality of cooling fins, and the plurality of cooling fins are disposed on the substrate and form a plurality of flow channels.

2. The cooling system as claimed in claim 1, wherein each of the plurality of cooling fins has a plurality of connected wave crests to form a wave shape, and a pitch between any adjacent two of the plurality of wave crests is the same as another pitch between any other adjacent two of the plurality of wave crests.

3. The cooling system as claimed in claim 1, wherein the at least one cooling structure further comprises a cover, covering the substrate, and the cover and the substrate jointly accommodate the plurality of cooling fins.

4. The cooling system as claimed in claim 1, further comprising a manifold component, connected to the at least one cooling structure, wherein the manifold component comprises an inlet branch pipe and an outlet branch pipe, and a fluid flows from a source along an inflow direction through the inlet branch pipe, the plurality of flow channels of the at least one cooling structure, and the outlet branch pipe.

5. The cooling system as claimed in claim 4, wherein the at least one cooling structure comprises two cooling structures, the two cooling structures are respectively connected to the top surface and the bottom surface of the power module, the inlet branch pipe comprises two inlet ports connected to the two cooling structures, the two inlet ports respectively have an inlet pipe diameter of a different size, the outlet branch pipe comprises two outlet ports connected to the two cooling structures, and the two outlet ports respectively have an outlet pipe diameter of a different size.

6. The cooling system as claimed in claim 5, wherein the inlet branch pipe and the outlet branch pipe are respectively located on other two opposite sides of the power module.

7. The cooling system as claimed in claim 5, wherein the inlet branch pipe and the outlet branch pipe are located on a same side of the power module.

8. The cooling system as claimed in claim 5, wherein an inlet pipe diameter corresponding to one of the two inlet ports close to the source is larger than another inlet pipe diameter corresponding to another one of the two inlet ports away from the source.

9. The cooling system as claimed in claim 5, wherein an outlet pipe diameter corresponding to one of the two outlet ports close to the source is smaller than another outlet pipe diameter corresponding to another one of the two outlet ports away from the source.

10. The cooling system as claimed in claim 5, wherein the manifold component further comprises two valve body components, respectively disposed on each of the two inlet ports or each of the two outlet ports.

11. A cooling system, comprising:
at least two power modules, each of the at least two power modules having a top surface and a bottom surface opposite to each other;
a plurality of cooling structures, connected to at least one of the top surface and the bottom surface of the each of the at least two power modules, wherein each of the plurality of cooling structures comprises a substrate and a plurality of cooling fins, and the plurality of cooling fins are disposed on the substrate and form a plurality of flow channels; and
a manifold component, connected to the plurality of cooling structures, the manifold component comprising:
at least one inlet branch pipe, comprising a plurality of inlet ports connected to the plurality of cooling structures, wherein the plurality of inlet ports have a plurality of inlet pipe diameters of a different size; and
at least one outlet branch pipe, comprising a plurality of outlet ports connected to the plurality of cooling structures, wherein the plurality of outlet ports have a plurality of outlet pipe diameters of a different size,
wherein a fluid flows from at least one source along an inflow direction through the at least one inlet branch pipe, the plurality of flow channels of the plurality of cooling structures, and the at least one outlet branch pipe.

12. The cooling system as claimed in claim 11, wherein the plurality of cooling structures are located on a same plane.

13. The cooling system as claimed in claim 11, wherein the plurality of cooling structures are connected to the top surface and the bottom surface of the each of the at least two power modules.

14. The cooling system as claimed in claim 11, wherein the at least one inlet branch pipe comprises two inlet branch pipes, the at least one outlet branch pipe comprises two outlet branch pipes, one of the two inlet branch pipes and a corresponding one of the two outlet branch pipes are connected to a part of the plurality of cooling structures, and another one of the two inlet branch pipes and another corresponding one of the two outlet branch pipes are connected to another part of the plurality of cooling structures.

15. The cooling system as claimed in claim 11, wherein the at least one inlet branch pipe is located on one side of the at least two power modules, and the at least one outlet branch pipe is located on another side of the at least two power modules.

16. The cooling system as claimed in claim 14, wherein the one of the two inlet branch pipes and the corresponding one of the two outlet branch pipes are located on one side of the at least two power modules, and the another one of the two inlet branch pipes and the another corresponding one of the two outlet branch pipes are located on another side of the at least two power modules.

17. The cooling system as claimed in claim 11, wherein the at least one inlet branch pipe and the at least one outlet branch pipe are located on two opposite sides of the at least two power modules.

18. The cooling system as claimed in claim 11, wherein the at least one inlet branch pipe and the at least one outlet branch pipe are located on a same side of the at least two power modules.

19. The cooling system as claimed in claim 11, wherein the at least two power modules are arranged along an arrangement direction, and the arrangement direction is perpendicular to a normal direction of the top surface.

20. The cooling system as claimed in claim 11, wherein the at least two power modules and the plurality of cooling structures are arranged along an arrangement direction, and the arrangement direction is parallel to a normal direction of the top surface.

21. The cooling system as claimed in claim 20, wherein any two adjacent ones of the at least two power modules are connected to a same one of the plurality of cooling structures.

22. The cooling system as claimed in claim 11, wherein the plurality of inlet pipe diameters decrease progressively as being away from the at least one source.

23. The cooling system as claimed in claim 11, wherein the plurality of outlet pipe diameters increase progressively as being away from the at least one source.

24. The cooling system as claimed in claim 11, wherein the manifold component further comprises a plurality of valve body components disposed on the plurality of inlet ports.

25. A control method of a cooling system, wherein the cooling system comprises at least two power modules, a plurality of cooling structures, and a manifold component, the plurality of cooling structures are connected to at least one of a top surface and a bottom surface of each of the at least two power modules, at least one inlet branch pipe of the manifold component is connected to a plurality of inlet ports of the plurality of cooling structures, at least one outlet branch pipe of the manifold component is connected to a plurality of outlet ports of the plurality of cooling structures, and a plurality of valve body components are disposed on the plurality of inlet ports, the control method comprising:
sensing a temperature of the at least two power modules to obtain a plurality of temperature data;
analyzing the plurality of temperature data;
determining whether the temperature of the at least two power modules is abnormal, and when a determination result indicates abnormality, adjusting the temperature of the at least two power modules to stabilize the temperature of the at least two power modules; and
when the determination result indicates no abnormality or the temperature of the at least two power modules being stabilized, recording and learning the plurality of temperature data and an adjustment process.

26. The control method as claimed in claim 25, wherein adjusting the temperature of the at least two power modules comprises:
performing a model prediction and providing a control temperature decision through an artificial intelligence system;
adjusting the plurality of valve body components to control a flow rate of a fluid flowing through the plurality of cooling structures; and
sensing the temperature of the at least two power modules again to re-determine whether the temperature of the at least two power modules are stabilized.
